(19) United States
(12) Patent Application Publication
(10) Pub. No.: US 2026/0363099 A1
(43) Pub. Date: Nov. 12, 2026

(54) POWER SEMICONDUCTOR PACKAGE INCLUDING A SOLDER JOINT FORMED BY ULTRASONIC SOLDERING AND FABRICATION METHOD

(71) Applicant: Infineon Technologies AG, Neubiberg (DE)

(72) Inventors: Michael Fügl, Neumarkt (DE); Thorsten Scharf, Lappesdorf (DE); Franz Zollner, Sinzing (DE)

(21) Appl. No.: 19/667,823

(22) Filed: May 5, 2026

(30) Foreign Application Priority Data
May 6, 2025 (DE) 102025117189.0

(51) Int. Cl. H10W 70/40; H10W 40/20; H10W 70/04; H10W 90/00

(52) U.S. Cl. CPC H10W 70/479; H10W 40/235; H10W 70/047; H10W 70/457; H10W 90/757

(57) ABSTRACT

A power semiconductor package includes: a leadframe having a first side and an opposite second side; a power semiconductor die arranged on the second side of the leadframe; a solder layer having an active solder material arranged on the first side of the leadframe; an electrically insulating sheet arranged on the solder layer and mechanically fixed to the leadframe by the solder layer; and an encapsulation body encapsulating the power semiconductor die. The electrically insulating sheet is at least partially exposed from a first side of the encapsulation body. The active solder material forms an ultrasonic soldering joint with the electrically insulating sheet.

### TECHNICAL FIELD

The present disclosure relates to power semiconductor packages, in particular power semiconductor packages comprising at least one solder joint formed via an ultrasonic soldering process, as well as to a method for fabricating such power semiconductor packages.

### BACKGROUND

A power semiconductor package may comprise a substrate, at least one power semiconductor die arranged on and electrically coupled to the substrate and an encapsulation body encapsulating the power semiconductor die and thereby protecting the power semiconductor die from environmental influences. The power semiconductor die may be arranged on one side of the substrate and an opposite further side of the substrate may be exposed from the encapsulation body. In this manner, a heatsink can be coupled to the exposed side of the substrate in order to dissipate heat generated by the power semiconductor die during operation. In order to electrically isolate the heatsink from the power semiconductor die, the substrate may comprise an insulating layer arranged between two conductive layers, like a direct bonded copper (DBC) or an active metal braze (AMB). However, these types of substrates may be comparatively expensive. Furthermore, the fabrication processes of these types of substrate may set limits to the minimum thickness and/or the maximum thickness that the conductive layers and/or the insulating layer of these types of substrate can have. This in turn may for example limit the heat dissipation capabilities of a power semiconductor package which comprises these types of substrates. Improved power semiconductor packages and improved methods for fabricating a power semiconductor package may help with solving these and other problems.

### SUMMARY

Various aspects pertain to a power semiconductor package, comprising: a leadframe with a first side and an opposite second side, a power semiconductor die arranged on the second side of the leadframe, a solder layer comprising an active solder material arranged on the first side of the leadframe, an electrically insulating sheet arranged on the solder layer and mechanically fixed to the leadframe by the solder layer, and an encapsulation body encapsulating the power semiconductor die, wherein the electrically insulating sheet is at least partially exposed from a first side of the encapsulation body.

Various aspects pertain to a method for fabricating a power semiconductor package, the method comprising: providing a leadframe with a first side and an opposite second side, arranging a power semiconductor die on the second side of the leadframe, providing an electrically insulating sheet, performing an ultrasonic soldering process to solder a solder layer comprising an active solder material to the electrically insulating sheet, performing a further soldering process upon the solder layer to mechanically fix the electrically insulating sheet to the first side of the leadframe, and encapsulating with an encapsulation body the power semiconductor die such that the electrically insulating sheet is at least partially exposed from a first side of the encapsulation body.

Various aspects pertain to a power electronic assembly, comprising: the power semiconductor package outlined above, and a heatsink arranged over a second solder layer.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates a sectional view of a power semiconductor package comprising a power semiconductor die arranged on a die pad, wherein the die pad is a leadframe part and wherein the die pad is coupled to an electrically insulating sheet via a solder layer. The solder layer is joined to the electrically insulating sheet via a joint formed by ultrasonic soldering.

FIG. 2 schematically illustrates a sectional view of a power electronic assembly comprising the power semiconductor package of FIG. 1 coupled to a heatsink. The electrically insulating sheet isolates the leadframe from the heatsink.

FIG. 3 schematically illustrates a sectional view of a further power electronic assembly, similar to the power electronic assembly of FIG. 2, wherein a conductive layer is arranged between the heatsink and the electrically insulting sheet. The conductive layer is coupled to the electrically insulating sheet via a further solder layer, wherein the further solder layer is joined to the electrically insulating sheet using an ultrasonic soldering process.

FIG. 4 schematically illustrates an ultrasonic soldering process for joining a solder layer to an electrically insulating sheet.

FIGS. 5A and 5B schematically illustrate two exemplary processes of soldering the electrically insulating sheet to the leadframe. In the example of FIG. 5A, the electrically insulating sheet is soldered to the leadframe prior to fabricating an encapsulation body of the power semiconductor package and in FIG. 5B, the electrically insulating sheet is soldered to the leadframe after the encapsulation body has been fabricated.

FIG. 6 is a flow chart of an exemplary method for fabricating a power semiconductor package, wherein the method comprises a process of ultrasonic soldering.

### DETAILED DESCRIPTION

In the following detailed description, known structures and elements are shown in schematic form in order to facilitate describing one or more aspects of the disclosure. In this regard, directional terminology, such as "top", "bottom", "left", "right", "upper", "lower" etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms "include", "have", "with" or other variants thereof are used in either the detailed description or the claims, such terms are intended to be inclusive in a manner similar to the term "comprise". The terms "coupled" and "connected", along with derivatives thereof may be used. It should be understood that these terms may be used to indicate that two elements cooperate or interact with each other regardless whether they are in direct physical or electrical contact, or they are not in direct contact with each other; intervening elements or layers may be provided between the "bonded", "attached", or "connected" elements. However, it is also possible that the "bonded", "attached", or "connected" elements are in direct contact with each other. Also, the term "exemplary" is merely meant as an example, rather than the best or optimal.

A power semiconductor package may comprise various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, power integrated circuits, etc. The examples may also use semiconductor dies comprising MOS transistor structures or vertical transistor structures like, for example, IGBT (Insulated Gate Bipolar Transistor) structures or, in general, transistor structures in which at least one electrical contact pad is arranged on a first main side of the semiconductor die and at least one other electrical contact pad is arranged on a second main side of the semiconductor die, opposite to the first main side of the semiconductor die.

The semiconductor dies(s) can be manufactured from a specific semiconductor material, for example Si, SiC, SiGe, GaAs, GaN, or from any other semiconductor material, and, furthermore, may contain one or more of inorganic and organic materials that are not semiconductors, such as for example insulators, plastics or metals.

In several examples layers or layer stacks are applied to one another or materials are applied or deposited onto layers. It should be appreciated that any such terms as "applied" or "deposited" are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

An efficient power semiconductor package, an efficient power electronic assembly and an efficient method for fabricating a power semiconductor package may for example reduce material consumption, ohmic losses, chemical waste, etc. and may thus enable energy and/or resource savings. Improved power semiconductor packages, improved power electronic assemblies and improved methods for fabricating a power semiconductor package, as specified in this description, may thus at least indirectly contribute to green technology solutions, i.e. climate-friendly solutions providing a mitigation of energy and/or resource use.

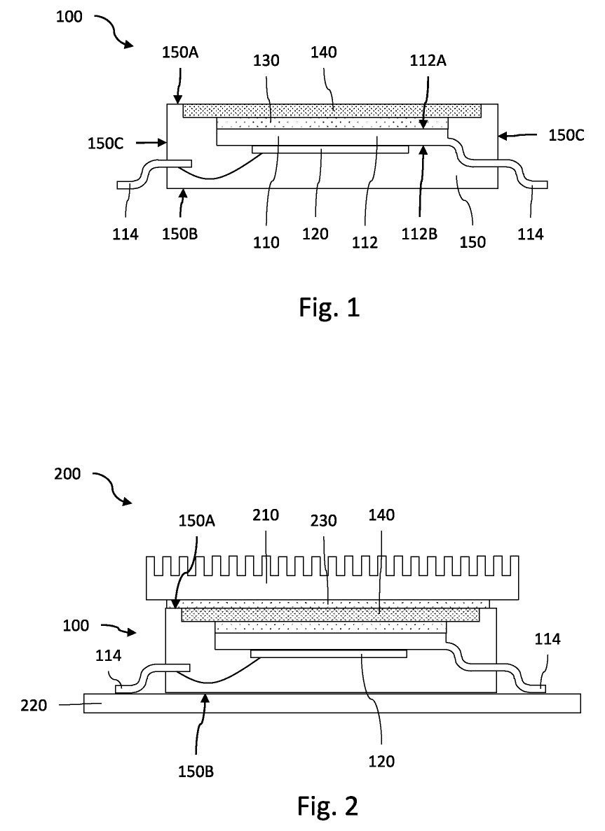

FIG. 1 schematically shows a power semiconductor package 100 comprising a leadframe 110, a power semiconductor die 120, a solder layer 130, an electrically insulating sheet 140 and an encapsulation body 150.

The power semiconductor package 100 may be configured for use in any suitable application, for example in automotive applications, industrial applications or household applications. The power semiconductor package 100 may be a discrete device, meaning that the power semiconductor package 100 comprises a single topological switch or a single semiconductor die. However, it is also possible that the power semiconductor package 100 comprises any suitable electrical circuit, for example a half bridge circuit, a full bridge circuit, a converter circuit, an inverter circuit, etc. According to a specific example, the power semiconductor package 100 is configured for use in the main inverter of the electric engine of an electric vehicle. The power semiconductor package 100 may, for example, provide the half bridge of one of the three phases of a 3-phase electric power engine of an electric vehicle.

The power semiconductor package 100 may for example be configured to operate with a voltage of 100V or more, or 500V or more, or 1.2kV or more, or even 2kV or more. The power semiconductor package 100 may, for example, be configured to operate with a load current of 1A or more, 10A or more, 50A or more, or even 100A or more.

The leadframe 110 may comprise a die pad 112 with a first side 112A and an opposite second side 112B. The power semiconductor package 100 may comprise a single die pad 112. However, it is also possible that the power semiconductor package 100 comprises a plurality of die pads 112.

The leadframe 110 may comprise or consist of any suitable metal or metal alloy, for example Cu. The leadframe 110, in particular portions of the leadframe 110 which are exposed from the encapsulation body 150, may be covered by a plating, e.g. a Ni plating. This however is not necessarily the case and it is also possible that the leadframe 110 is not plated.

The die pad 112 may have any suitable thickness, for example a thickness measured between the first and second sides 112A, 112B of at least 100µm, or at least 150µm, or at least 200µm, or at least 300µm, or at least 400µm, or at least 500µm. The die pad 112 may be configured to act as a heat spreader for heat generated by the power semiconductor die 120 during operation.

The leadframe 110 may further comprise one or more external contacts 114 exposed from the encapsulation body 150. The external contacts 114 may comprise one or more power contacts configured to carry a load current and one or more sensing or control contacts configured to carry sensing or control signals. According to an example, the die pad 112 and at least one of the external contacts 114 may be a monolithic part.

The power semiconductor die 120 is arranged on the second side 112B of the die pad 112. According to an example, a single power semiconductor die 120 is arranged on the die pad 112. According to another example, two or more power semiconductor dies 120 are arranged on the die pad 112 and may be electrically connected by the die pad 112, for example in a parallel connection. The two or more power semiconductor dies 120 may be the same type of die. However, it is also possible that the two or more power semiconductor dies 120 are different types of dies.

The power semiconductor die 120 may comprise a first side and an opposite second side, wherein the first side faces the die pad 112. A first load electrode, e.g. a drain electrode or a collector electrode, may be arranged on the first side and may be connected to the die pad 112 via e.g. a solder joint, a sintered joint or a joint comprising conductive glue. A second load electrode, e.g. a source electrode or an emitter electrode, may be arranged on the second side and may for example be connected to an external contact 114 of the leadframe 110 via e.g. a connector like a bond wire, a ribbon or a clip (alternatively, the clip itself may provide the external terminal). According to another example, the positions of the first and second load terminals is reversed. The second side of the power semiconductor die 120 may also comprise a gate electrode.

The solder layer 130 is arranged on the first side 112A of the die pad 112. According to an example, the solder layer 130 completely covers the first side 112A. According to another example, the solder layer 130 only partially covers the first side 112A, for example no more than 95%, or no more than 90%, or no more than 80%, or no more than 70%. The solder layer 130 may, for example, only cover an inner portion of the first side 112A and an outer margin of the first side 112A may be free of the solder layer 130. According to yet another example, the solder layer 130 may protrude from a contour of the die pad 112.

The solder layer 130 may have any suitable thickness measured perpendicular to the first side 112A of the die pad 112. For example, the solder layer 130 may have a thickness in the range of about 100nm to about 200µm. The lower limit of this range may also be about 500nm, or about 1µm, or about 10µm and the upper limit may also be about 100µm or about 50µm, or about 30µm.

The solder layer 130 comprises an active solder material configured for use in an ultrasonic soldering process. Such an active solder material may for example comprise one or more of In, Ti, Hf, Zr and/or one or more rare earth elements, in particular Ce, La, or Lu. Ultrasonic soldering is a soldering process that uses heat and ultrasonic energy provided by a sonotrode to melt active solder materials and remove surface oxides, thereby forming a joint. Ultrasonic soldering allows joining materials such as glass, ceramics, composites, hard to solder metals and other components that cannot normally be soldered.

The electrically insulating sheet 140 is arranged on the solder layer 130. In particular, the electrically insulating sheet 140 may be arranged directly on the solder layer 130, without any intervening layers, and the solder layer 130 in turn may be arranged directly on the first side 112A of the die pad 112. The electrically insulating sheet 140 is mechanically fixed to the die pad 112 by the solder layer 130. Furthermore, the active solder material of the solder layer 130 forms an ultrasonic soldering joint with the electrically insulating sheet 140, wherein the ultrasonic soldering joint is a joint formed by an ultrasonic soldering process. The solder layer 130 also forms a solder joint with the die pad 112, for example a soft solder joint. The solder joint between the solder layer 130 and the die pad 112 may be fabricated using any suitable soldering process, for example a reflow soldering process.

The electrically insulating sheet 140 may have any suitable thickness measured perpendicular to the first side 112A of the die pad 112. For example, the thickness of the electrically insulating sheet 140 may be in the range of about 50µm to about 2mm. The lower limit of this range may also be about 80µm, or about 100µm, or about 150µm and the upper limit may also be about 1mm, or about 500µm, or about 300µm, or about 200µm.

The electrically insulating sheet 140 may have any suitable lateral dimensions measured in a plane parallel to the first side 112A of the die pad 112. The electrically insulating sheet 140 may have lateral extensions which are at least equal to the extensions of the die pad 112, such that the electrically insulating sheet 140 completely covers the die pad 112 as viewed from above the first side 112A of the die pad 112. As shown in the example of FIG. 1, the electrically insulating sheet 140 may also protrude from all sides of the contour of the die pad 112 as viewed from above the first side 112A. The electrically insulating sheet 140 may for example protrude from all sides by at least about 0.5mm, or at least about 1mm, or at least about 2mm, or at least about 5mm, or at least about 10mm.

The electrically insulating sheet 140 may comprise or consist of any suitable electrically insulating material or material composition. For example, the electrically insulating sheet 140 may comprises or consists of ceramic, for example aluminum oxide or aluminum nitride, or diamond, in particular polycrystalline diamond or monocrystalline diamond. The electrically insulating sheet 140 may in particular comprise or consist of a material or material composition that cannot normally be soldered, hence an ultrasonic soldering process is required.

The encapsulation body 150 encapsulates the power semiconductor die 120. The encapsulation body 150 comprises a first side 150A, an opposite second side 150B and lateral sides 150C connecting the first and second sides 150A, 150B. The electrically insulating sheet 140 is at least partially exposed from the first side 150A of the encapsulation body 150.

The external contacts 114 may, for example, be exposed from one or more of the lateral sides 150C of the encapsulation body 150, in particular from opposite ones of the lateral sides 150C. The first and second sides 150A, 150B may be free of any external contacts 114.

According to an example, the encapsulation body 150 comprises or consists of a molded body. The molded body may be fabricated using any suitable molding process, for example compression molding, injection molding or transfer molding. The encapsulation body 150 may for example comprise inorganic filler particles, configured to reduce the thermal resistance of the encapsulation body 150.

FIG. 2 schematically shows a power electronic assembly 200 comprising the power semiconductor package 100 and a heatsink 210. The power electronic assembly 200 may further optionally comprise a board 220.

The power semiconductor package 100 may be arranged over the board 220 such that the second side 150B of the encapsulation body 150 faces the board. The external contacts 114 are electrically connected to the board via e.g. solder joints, sintered joints, welded joints or joints comprising conductive glue. As shown in FIG. 2, the power semiconductor package 100 may be a surface-mount device (SMD). However, it is also possible that the power semiconductor package 100 is a through-hole device (THD).

The board 220 may for example be a printed circuit board (PCB). The board 220 may be configured to carry both load currents as well as sensing or control signals of the power semiconductor package 100. According to an example, the board 220 plays no part or only a minor part in a heat dissipation scheme for heat generated by the power semiconductor package 100 during operation. Most or even all of the generated heat may be dissipated via the heatsink 210. In other words, the power semiconductor package 100 may be a single side cooled (SSC) device.

The heatsink 210 is arranged over the first side 150A of the encapsulation body 150. The electrically insulating sheet 140 isolates the die pad 112 and therefore the power semiconductor die 120 from the heatsink 210. The heatsink 210 may, for example, comprise or consist of a suitable metal or metal alloy. For example, the heatsink 210 may comprise or consist of Al or Cu. The heatsink 210 may also comprise or consist of ceramic. According to an example, the heatsink 210 comprises or consists of a 3D-printed piece.

As shown in FIG. 2, a side of the heatsink 210 facing away from the power semiconductor package 100 may comprise a plurality of cooling elements or cooling fins configured to be in contact with a cooling fluid. The cooling fluid may for example be water or air.

According to an example, the heatsink 210 is coupled to the power semiconductor package 100 via a second solder layer 230 arranged on a side of the electrically insulating sheet 140 that faces away from the die pad 112. The second solder layer 230 may comprise an active solder material, for example the same active solder material as the solder layer 130. The second solder layer 230 may be coupled to the electrically insulating sheet 140 using a further ultrasonic soldering process. In other words, the active solder material of the second solder layer 230 may form a second ultrasonic soldering joint with the electrically insulating sheet 140. A thickness of the second solder layer 230 may for example be in the same range as disclosed further above with respect to the solder layer 130.

According to an example, no layer of thermal interface material (TIM) is arranged between the heatsink 210 and the die pad 112. A TIM layer may have a comparably high thermal resistance and may therefore negatively affect the heat dissipation capabilities of the power electronic assembly 200. According to another, example, a TIM layer is arranged between the heatsink 210 and the electrically insulating sheet 140. In this case, the TIM layer may replace the second solder layer 230, meaning that the heatsink 210 is not soldered to the electrically insulating sheet 140.

The power semiconductor package 100 may offer several advantages compared to a package comprising a substrate like a direct bonded copper (DBC), a direct bonded aluminum (DBA), an active metal braze (AMB), etc. in place of the leadframe based die pad 112 and the electrically insulating sheet 140. For example, due to limitations of the manufacturing process of e.g. an AMB, the ceramic layer in such a substrate has a certain minimum thickness, which limits the achievable minimum thermal resistance when using such a substrate. The manufacturing process also limits the maximum thickness of the Cu layers that is economically achievable. However, a higher Cu layer thickness may be desirable, for example, to improve the heat spreading capabilities. Furthermore, in order to prevent warpage of a substrate like an AMB or a DBC, it may be necessary to fabricate the substrate with Cu layers of identical thickness on both sides of the ceramic layer, even if the application in the package would only require a single Cu layer.

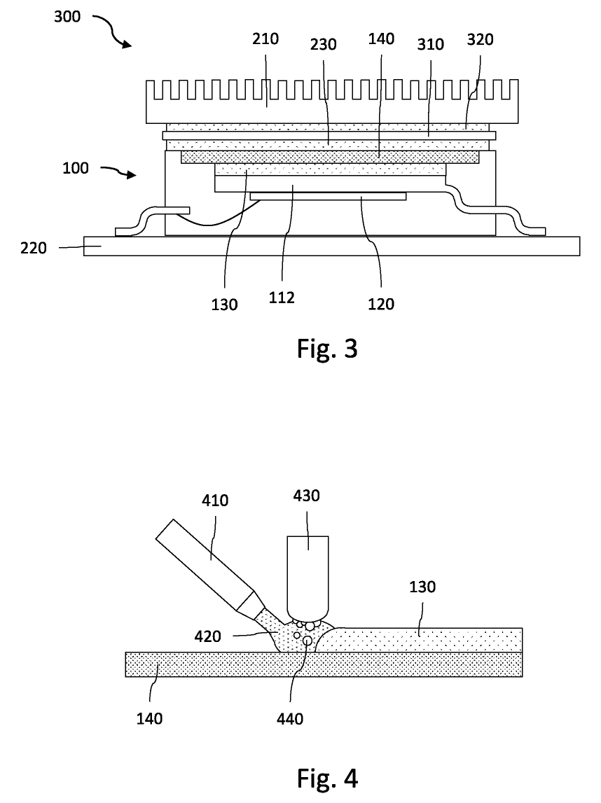

FIG. 3 schematically shows a further power electronic assembly 300, which may be similar or identical to the power electronic assembly 200, except for the differences described in the following.

In particular, the power electronic assembly 300 may comprise all components described with respect to the power electronic assembly 200 and the power electronic assembly 300 additionally comprises an electrically conductive layer 310 arranged between the electrically insulating sheet 140 and the heatsink 210.

The electrically conductive layer 310 may comprise or consist of any suitable metal or metal alloy. For example, the electrically conductive layer 310 may comprise or consist of Al or Cu. The electrically conductive layer 310 may have any suitable thickness and any suitable lateral extensions. For example, the electrically conductive layer 310 may have a thickness in the range of about 100µm to about 1mm. The lower limit of this range may also be about 150µm, or about 300µm and the upper limit may also be about 700µm or about 500µm. The electrically conductive layer 310 may for example protrude from a contour of the die pad 112 from all sides, as viewed from above the electrically conductive layer 310. The electrically conductive layer 310 may for example have similar lateral extensions as the electrically insulating sheet 140.

The electrically conductive layer 310 may be coupled to the electrically insulating sheet 140 via the second solder layer 230. The electrically conductive layer 310 may form a soft solder joint or a reflow solder joint with the second solder layer 230. According to an example, the electrically conductive layer 310 is configured to be soldered to the heatsink 210. To this effect, a third solder layer 320 may be arranged between the electrically conductive layer 310 and the heatsink 210.

The third solder layer 320 may, for example, comprise the active solder material. However, in the case that no ultrasonic soldering process has to be performed on the third solder layer 320 (because the heatsink 210 comprises or consists of a material that is readily solderable), it is also possible that the third solder layer 320 comprises a different solder material, for example a soft solder material.

According to an example, the electrically conductive layer 310 is configured to act as a heat spreader. In this case, the electrically conductive layer 310 may improve the distribution of heat generated by the power semiconductor die 120 across the bulk of the heatsink 210.

FIG. 4 schematically shows an exemplary ultrasonic soldering process which may be used to join the solder layer 130 to the electrically insulating sheet 140.

As shown in FIG. 4, a nozzle 410 may be used to deposit liquid solder 420 onto a surface of the electrically insulating sheet 140. A sonotrode 430 is used to apply heat and ultrasonic energy to the liquid solder 420. The ultrasonic energy generates cavities 440 in the liquid solder 420, which may break up surface oxides on the substrate, thereby allowing the liquid solder to wet the substrate, i.e. the electrically insulating sheet 140. Once the liquid solder 420 has cured, the solder layer 130 is formed.

According to an example, a second ultrasonic soldering process may be used to fabricate the second solder layer 230 on the opposite surface of the electrically insulating sheet 140.

The ultrasonic soldering process may be performed at comparatively low processing temperatures, for example processing temperatures of no more than 220° C, or no more than 180° C, or no more than 150° C. By comparison, fabricating a substrate like an AMB may comprise comparatively high processing temperatures of e.g. 350° C or more. Such higher temperatures may, for example, more readily cause warpage of the substrate.

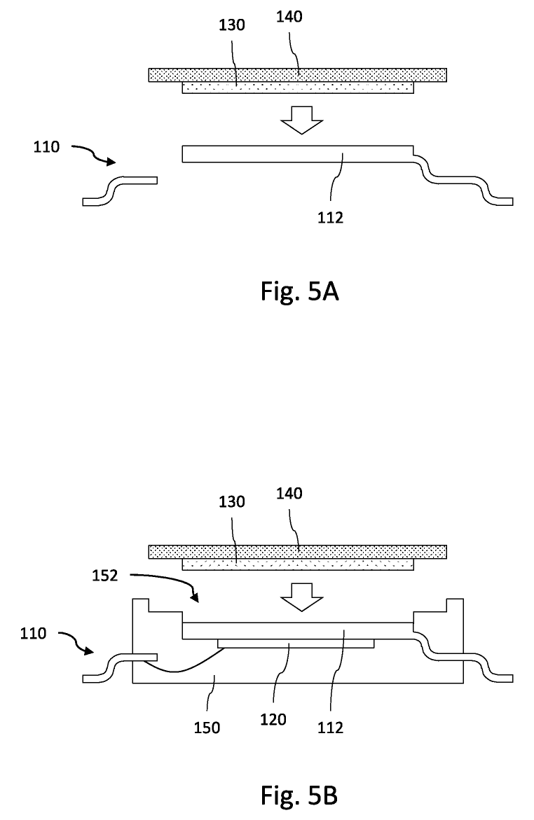

FIGS. 5A and 5B schematically show two different exemplary processes of coupling the electrically insulating sheet 140 to the leadframe 110.

In the process shown in FIG. 5A, the electrically insulating sheet 140 with the applied solder layer 130 is soldered to the leadframe 110 prior to an encapsulation process. In other words, the encapsulation body 150 has not been formed yet when the electrically insulating sheet 140 is soldered to the leadframe 110 (in particular, to the die pad 112).

The electrically insulating sheet 140 may be soldered to the leadframe 110 prior to arranging the power semiconductor die 120 on the die pad 112, compare FIG. 5A. However, it is also possible that the electrically insulating sheet 140 is soldered to the leadframe 110 after the power semiconductor die 120 has been arranged on the die pad 112 (i.e. soldered, sintered or glued to the die pad 112).

In the process shown in FIG. 5B, the electrically insulating sheet 140 is soldered to the leadframe 110 after the encapsulation body 150 has been fabricated. To this effect, the encapsulation body 150 may comprise an opening 152, wherein the die pad 112 is exposed from the encapsulation body 150 in the opening. Fabricating the opening 152 may for example comprise using a mold tool with a suitable formed protrusion and/or using a removal process to remove encapsulation material from above the die pad 112. Such a removal process may for example comprise a grinding process.

According to another example, the encapsulation body 150 does not comprise the opening 152. Instead, the encapsulation body 150 is completely removed above the die pad 112 such that an upper side of the die pad 112 and the first side 150A of the encapsulation body 150 are essentially coplanar.

The process of soldering the electrically insulating sheet 140 to the die pad 112 of FIGS. 5A-5B may for example comprise a soft soldering process or a reflow soldering process.

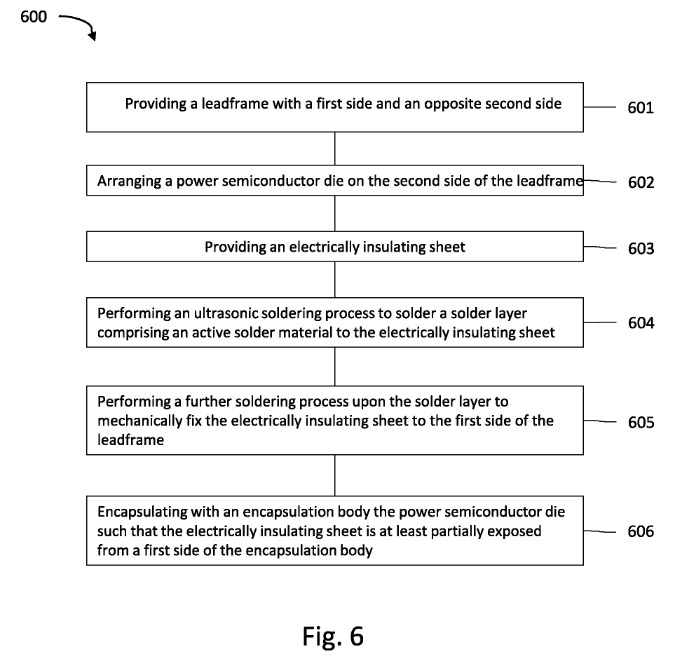

FIG. 6 is a flow chart of an exemplary method 600 for fabricating a power semiconductor package. The method 600 may for example be used to fabricate the power semiconductor package 100.

The method 600 comprises at 601 a process of providing a leadframe comprising a die pad with a first side and an opposite second side, at 602 a process of arranging a power semiconductor die on the second side of the die pad, at 603 a process of providing an electrically insulating sheet, at 604 a process of performing an ultrasonic soldering process to solder a solder layer comprising an active solder material to the electrically insulating sheet, at 605 a process of performing a further soldering process upon the solder layer to mechanically fix the electrically insulating sheet to the first side of the die pad, and at 606 a process of encapsulating with an encapsulation body the power semiconductor die such that the electrically insulating sheet is at least partially exposed from a first side of the encapsulation body.

In the following, the power semiconductor package and the method for fabricating a power semiconductor package are further explained using specific examples.

Example 1 is a power semiconductor package, comprising: a leadframe comprising a die pad having a first side and an opposite second side, a power semiconductor die arranged on the second side of the die pad, a solder layer comprising an active solder material arranged on the first side of the die pad, an electrically insulating sheet arranged on the solder layer and mechanically fixed to the die pad by the solder layer, and an encapsulation body encapsulating the power semiconductor die, wherein the electrically insulating sheet is at least partially exposed from a first side of the encapsulation body.

Example 2 is the power semiconductor package of example 1, wherein the active solder material forms an ultrasonic soldering joint with the electrically insulating sheet.

Example 3 is the power semiconductor package of example 1 or 2, wherein the active solder material forms a soft soldering joint with the die pad.

Example 4 is the power semiconductor package of example 1 or 3, wherein the active solder material comprises one or more of In, Ti, Hf, Zr and/or one or more rare earth elements, in particular Ce, La, or Lu.

Example 5 is the power semiconductor package of one of the preceding examples, wherein the electrically insulating sheet comprises or consists of ceramic or diamond.

Example 6 is the power semiconductor package of one of the preceding examples, wherein the electrically insulating sheet has a thickness measured perpendicular to the first side of the die pad of no more than 150µm.

Example 7 is the power semiconductor package of one of the preceding examples, wherein the die pad has a thickness measured between the first and second sides of at least 200µm.

Example 8 is the power semiconductor package of one of the preceding examples, wherein the leadframe further comprises one or more external contacts exposed from at least one lateral side of the encapsulation body.

Example 9 is the power semiconductor package of one of the preceding examples, further comprising: a second solder layer arranged on a side of the electrically insulating sheet that faces away from the die pad, the second solder layer comprising the active solder material, and wherein the active solder material of the second solder layer forms a second ultrasonic soldering joint with the electrically insulating sheet.

Example 10 is the power semiconductor package of example 9, further comprising: an electrically conductive layer arranged on the second solder layer and soldered to the electrically insulating sheet by the second solder layer.

Example 11 is a method for fabricating a power semiconductor package, the method comprising: providing a leadframe comprising a die pad with a first side and an opposite second side, arranging a power semiconductor die on the second side of the die pad, providing an electrically insulating sheet, performing an ultrasonic soldering process to solder a solder layer comprising an active solder material to the electrically insulating sheet, performing a further soldering process upon the solder layer to mechanically fix the electrically insulating sheet to the first side of the die pad, and encapsulating with an encapsulation body the power semiconductor die such that the electrically insulating sheet is at least partially exposed from a first side of the encapsulation body.

Example 12 is the method of example 11, wherein the further soldering process is a soft soldering process.

Example 13 is the method of example 11 or 12, wherein the ultrasonic soldering process is performed at a process temperature of no more than 230°C.

Example 14 is the method of one of examples 11 to 13, wherein the electrically insulating sheet is soldered to the first side of the die pad prior to encapsulating the power semiconductor die.

Example 15 is the method of one of examples 11 to 13, wherein the electrically insulating sheet is soldered to the first side of the die pad after encapsulating the power semiconductor die.

Example 16 is the method of one of claims 11 to 15, further comprising: performing a second ultrasonic soldering process to solder a second solder layer comprising the active solder material to a side of the electrically insulating sheet that faces away from the die pad.

Example 17 is a power electronic assembly, comprising: the power semiconductor package of example 9 or 10, and a heatsink arranged over the second solder layer.

Example 18 is the power electronic assembly of example 17, wherein the heatsink comprises or consists of ceramic.

Example 19 is the power electronic assembly of example 17 or 18, wherein the heatsink is a 3D-printed piece.

Example 20 is an apparatus comprising means for performing the method of anyone of examples 11 to 16.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor package, comprising:
a leadframe having a first side and an opposite second side;
a power semiconductor die arranged on the second side of the leadframe;
a solder layer comprising an active solder material arranged on the first side of the leadframe;
an electrically insulating sheet arranged on the solder layer and mechanically fixed to the leadframe by the solder layer; and
an encapsulation body encapsulating the power semiconductor die,
wherein the electrically insulating sheet is at least partially exposed from a first side of the encapsulation body.

2. The power semiconductor package of claim 1, wherein the active solder material forms an ultrasonic soldering joint with the electrically insulating sheet.

3. The power semiconductor package of claim 1, wherein the active solder material forms a soft soldering joint with the leadframe.

4. The power semiconductor package of claim 1, wherein the active solder material comprises one or more of In, Ti, Hf, Zr and/or one or more rare earth elements.

5. The power semiconductor package of claim 1, wherein the electrically insulating sheet comprises a ceramic, diamond or glass.

6. The power semiconductor package of claim 1, wherein the electrically insulating sheet has a thickness of no more than 150µm measured perpendicular to the first side of the leadframe.

7. The power semiconductor package of claim 1, wherein the leadframe has a thickness of at least 200µm measured between the first and second sides.

8. The power semiconductor package of claim 1, wherein the leadframe further comprises one or more external contacts exposed from at least one lateral side of the encapsulation body.

9. The power semiconductor package of claim 1, further comprising:
a second solder layer arranged on a side of the electrically insulating sheet that faces away from the leadframe, the second solder layer comprising the active solder material,
wherein the active solder material of the second solder layer forms an ultrasonic soldering joint with the electrically insulating sheet.

10. The power semiconductor package of claim 9, further comprising:
an electrically conductive layer arranged on the second solder layer and soldered to the electrically insulating sheet by the second solder layer.

11. A power electronic assembly, comprising:
the power semiconductor package of claim 9; and
a heatsink arranged over the second solder layer.

12. The power electronic assembly of claim 11, wherein the heatsink comprises a ceramic.

13. The power electronic assembly of claim 11, wherein the heatsink is a 3D-printed piece.

14. A method for fabricating a power semiconductor package, the method comprising:
providing a leadframe having a first side and an opposite second side;
arranging a power semiconductor die on the second side of the leadframe;
providing an electrically insulating sheet;
performing an ultrasonic soldering process to solder a solder layer comprising an active solder material to the electrically insulating sheet;
performing a further soldering process upon the solder layer to mechanically fix the electrically insulating sheet to the first side of the leadframe; and
encapsulating the power semiconductor die with an encapsulation body, such that the electrically insulating sheet is at least partially exposed from a first side of the encapsulation body.

15. The method of claim 14, wherein the further soldering process is a soft soldering process.

16. The method of claim 14, wherein the ultrasonic soldering process is performed at a process temperature of no more than 400°C.

17. The method of claim 16, wherein the process temperature is 260°C.

18. The method of claim 14, wherein the electrically insulating sheet is soldered to the first side of the leadframe prior to encapsulating the power semiconductor die.

19. The method of claim 14, wherein the electrically insulating sheet is soldered to the first side of the leadframe after encapsulating the power semiconductor die.

20. The method of claim 14, further comprising:
performing a second ultrasonic soldering process to solder a second solder layer comprising the active solder material to a side of the electrically insulating sheet that faces away from the leadframe.
